(19) United States
(12) Patent Application Publication
(10) Pub. No.: US 2023/0008518 A1
(43) Pub. Date: Jan. 12, 2023

(54) SEMICONDUCTOR PACKAGE AND MANUFACTURING METHOD THEREFOR

(71) Applicant: AMOSENSE CO.,LTD, Cheonan-si, Chungcheongnam-do (KR)

(72) Inventor: Ji-Hyung LEE, Cheonan-si (KR)

(73) Assignee: AMOSENSE CO.,LTD, Cheonan-si, Chungcheongnam-do (KR)

(21) Appl. No.: 17/786,488

(22) PCT Filed: Dec. 16, 2020
(86) PCT No.: PCT/KR2020/018390

§ 371 Date: Jun. 16, 2022

(30) Foreign Application Priority Data
Dec. 16, 2019 (KR) 10-2019-0168175

(51) Int. Cl. H01L 23/373; H01L 23/498; H01L 21/48; H01L 23/00

(52) U.S. Cl. CPC H01L 23/3735; H01L 23/49861; H01L 21/4853; H01L 24/48; H01L 24/45; H01L 2224/48227; H01L 2224/45169; H01L 2224/45139; H01L 2224/45144; H01L 2224/45147; H01L 2224/48105; H01L 2924/15153; H01L 2924/15747; H01L 2924/15787; H01L 2924/1517; H01L 2924/13051; H01L 2924/13062; H01L 2924/13091

(57) ABSTRACT

A semiconductor package of the present invention comprises a base plate, an insulating substrate, and a lead frame, wherein the base plate is made of a metallic material including Cu and Be—Cu. The present invention can ensure bonding reliability and thus prevent performance degradation of semiconductor devices.

### TECHNICAL FIELD

The present disclosure relates to a semiconductor package for protecting a semiconductor and a manufacturing method therefor.

### BACKGROUND ART

A semiconductor wafer includes hundreds or thousands of chips on which the same electrical circuits are printed. Each of the chips may not communicate with the outside only by itself. Accordingly, a semiconductor packaging process is to electrically connect wires to each of the chips to communicate with the outside, and to seal and package the chips to withstand external impacts, such as physical impact or chemical impact. In other words, the semiconductor packaging process called a die packaging process corresponds to the last process among processes of manufacturing a semiconductor device.

RF semiconductors are used in a wide variety of fields such as communication fields and military fields, and the environment in which the RF semiconductors are used is very diverse in terms of electrical and mechanical aspects. Accordingly, the semiconductor packaging process is very important to protect the RF semiconductors in various environments.

However, there may occur a problem in that the reliability of the bonding may be degraded due to a difference in the coefficient of thermal expansion upon bonding between packaging components, resulting in degrading the performance of the semiconductor device.

### SUMMARY OF INVENTION

### Technical Problem

The present disclosure has been made in efforts to solve the above problem, and an object of the present disclosure is to provide a semiconductor package capable of preventing performance of a semiconductor device from being degraded by securing bonding reliability, and a manufacturing method therefor.

### Solution to Problem

In order to achieve the object, according to features of the present disclosure, the semiconductor package includes a base plate, an insulating substrate bonded to the base plate, and having an opening formed therein, and a lead frame bonded to an electrode pattern provided on the insulating substrate, in which the base plate may be made of a metallic material containing Cu and Be—Cu. The thermal conductivity of the base plate may be 200 W/m·K or more.

The base plate may have a semiconductor chip such as an RF chip mounted on an area exposed by the opening.

The semiconductor chip and the electrode pattern may be electrically connected by a wire. Here, the wire may be connected to a portion of the electrode pattern in which the lead frame is not bonded.

The insulating substrate may have the electrode patterns provided on upper surfaces of both sides with the opening interposed therebetween.

The lead frame may include a first surface bonded to the electrode pattern and a second surface formed to extend from the first surface to the outside. Here, the second surface may be vertically bent, and an end of the second surface may be bent along a lower surface of the base plate.

In addition, the semiconductor package may further include a casing part bonded to the insulating substrate to seal a space above the opening. A through groove into which the lead frame is inserted may be provided under the casing part.

The insulating substrate may be made of a ceramic material containing 90 to 96 wt % of aluminum nitride or aluminum oxide, and the lead frame may be made of an Fe—Ni alloy or an Fe—Ni—Co alloy.

A method of manufacturing a semiconductor package includes bonding an insulating substrate having an opening to one surface of a base plate and bonding a lead frame to an electrode pattern provided on the insulating substrate, in which the base plate may be made of a metallic material including Cu and Be—Cu. At this time, the thermal conductivity of the base plate may be 200 W/m·K or more.

Meanwhile, the method may further include mounting a semiconductor chip on an area of the base plate exposed by the opening.

In addition, the method may further include electrically connecting a portion of the electrode pattern to which the lead frame is not bonded and the semiconductor chip using a wire.

In addition, the method may further include vertically bending a second surface formed to extend from a first surface of the lead frame bonded to the electrode pattern to the outside and bending an end of the second surface along a lower surface of the base plate.

### Advantageous Effects of Invention

According to the semiconductor package and the manufacturing method therefor according to the present disclosure, it is possible to manufacture the semiconductor package with the excellent thermal conductivity and reliability using Cu or Be—Cu that is inexpensive and has an excellent thermal conductivity.

### BRIEF DESCRIPTION OF DRAWINGS

FIG. 1 is a perspective view showing a semiconductor package according to an embodiment of the present disclosure.

FIG. 2 is an exploded perspective view of a semiconductor package in FIG. 1.

FIG. 3 is a cross-sectional view taken along line A-A′ in FIG. 1.

FIG. 4 is a cross-sectional view showing an example in which a casing part is provided in FIG. 3.

FIG. 5 is a perspective view showing an example in which a second surface of a lead frame is bent in the semiconductor package according to an embodiment of the present disclosure.

FIG. 6 is a cross-sectional view taken along line A-A′ in FIG. 5.

FIG. 7 is a picture showing a lateral cross section and a longitudinal cross section of a portion where an insulating substrate and a base plate are bonded in the semiconductor package according to an embodiment of the present disclosure.

FIG. 8 is a picture showing a result of performing a thermal impact test of the semiconductor package in FIG. 7.

FIG. 9 is a flowchart showing a method of manufacturing the semiconductor package according to an embodiment of the present disclosure.

### DESCRIPTION OF EMBODIMENTS

Hereinafter, embodiments of the present disclosure will be described in detail with reference to the accompanying drawings.

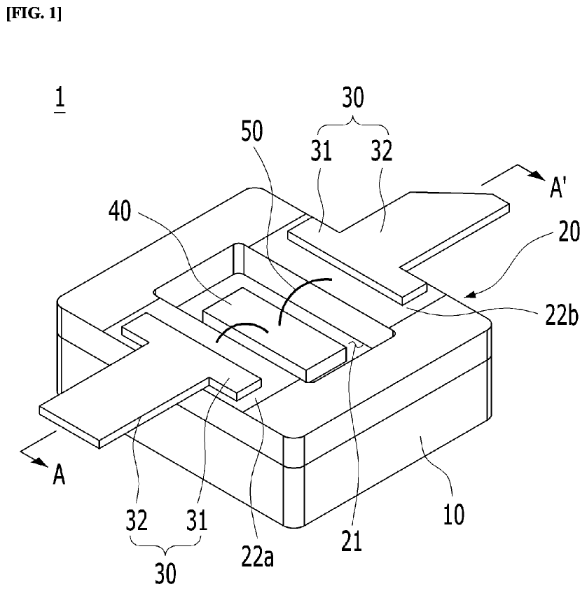

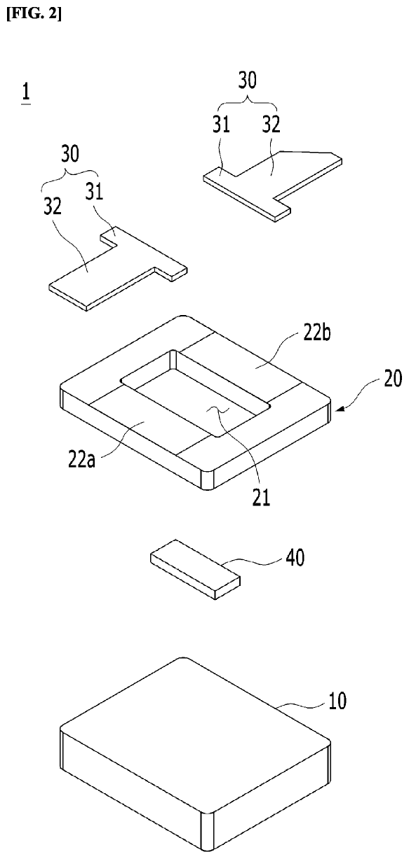

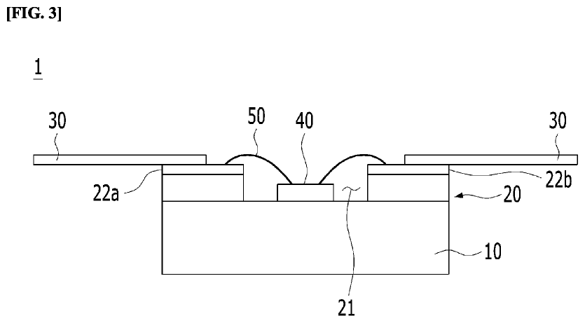

FIG. 1 is a perspective view showing a semiconductor package according to an embodiment of the present disclosure, FIG. 2 is an exploded perspective view of a semiconductor package in FIG. 1, and FIG. 3 is a cross-sectional view taken along line A-A′ in FIG. 1.

As shown in FIGS. 1 to 3, a semiconductor package 1 according to an embodiment of the present disclosure may have a semiconductor chip 40 such as an RF chip mounted therein, and may be used for an RF transistor capable of generating RF power by an electronic RF device. The RF power transistor may be, for example, any type of a transistor such as a metal-oxide semiconductor field-effect transistor (MOSFET), a lateral diffused metal-oxide semiconductor transistor (LDMOST), a bipolar junction transistor (BJT), a junction field-effect transistor (JFET), or a heterojunction bipolar transistor (HBT).

Specifically, the semiconductor package 1 according to the embodiment of the present disclosure may include a base plate 10, an insulating substrate 20 bonded to the base plate 10, and having an opening 21 formed therein, and a lead frame 30 bonded to electrode patterns 22a and 22b provided on the insulating substrate 20. The semiconductor package 1 may be completed by a molding, a casing, or the like.

The base plate 10 may have a semiconductor chip 40 mounted thereon and may be made of a metallic material. Specifically, the base plate 10 is preferably made of a metallic material including Cu and Be—Cu. The base plate 10 is bonded to the insulating substrate 20, and at this time, a material that satisfies conditions in which the coefficient of thermal expansion is 6.5 to 7.2 ppm/K, and the thermal conductivity is 200 W/m·K or more so that a problem does not occur in the bonded portion with the insulating substrate 20 has been mainly used. Accordingly, conventionally, an expensive metal such as CPC or super CPC in which Cu/Cu-Mo/Cu is sequentially stacked has been used as the base plate 10.

On the other hand, the semiconductor package 1 according to the embodiment of the present disclosure is characterized by using the base plate 10 made of a metallic material containing Cu and Be—Cu. Since copper (Cu) has the thermal conductivity of 400 W/m·K, heat generated from the semiconductor chip 40 may be effectively dissipated when the semiconductor chip 40 is mounted on the base plate 10. Beryllium copper (Be—Cu) is a material in which a small amount of beryllium (Be), for example, about 0.15 to 2.75% of beryllium is alloyed with copper. Beryllium copper has the same excellent properties as a mixture of the natures of copper and steel, and thus has an advantage of having high thermal conductivity of 200 W/m·K or more, and an excellent abrasion resistance.

Since copper and beryllium copper are inexpensive and have the excellent thermal conductivity, it is possible to prevent a phenomenon in which a problem occurs at the bonded portion with the insulating substrate 20 by an external temperature change, heat generated from the semiconductor chip 40, or the like when used as the base plate 10. In other words, in the semiconductor package 1 according to an embodiment of the present disclosure, it is possible to secure the reliability of the bonded portion.

The insulating substrate 20 may have the size corresponding to the base plate 10 and may be bonded to the base plate 10. In addition, the opening 21 may be formed in the insulating substrate 20. The opening 21 may be a space for mounting the semiconductor chip 40. In a state in which the insulating substrate 20 is bonded to the base plate 10, the semiconductor chip 40 may be mounted on an area of the base plate 10 exposed by the opening 21, and the mounted semiconductor chip 40 may be surrounded by an inner surface of the insulating substrate 20 around the opening 21.

The insulating substrate 20 may be made of a ceramic material such as zirconia toughened aluminum (ZTA), aluminum nitride (AlN), aluminum oxide (Al₂O₃), or silicon nitride (SiN, Si₃N₄). The insulating substrate 20 may also be made of a synthetic ceramic material including at least one of ZTA, aluminum nitride, aluminum oxide, and silicon nitride. For example, the insulating substrate 20 may be a material containing 4 to 10 wt % of ZTA and 90 to 96 wt % of aluminum nitride or aluminum oxide. The insulating substrate 20 may have the thickness of about 0.4 mm to 0.7 mm depending on a composition ratio.

The insulating substrate 20 may have a first electrode pattern 22a and a second electrode pattern 22b formed on both upper surfaces with the opening 21 interposed therebetween. The lead frame 30 may be bonded to one side of each of the first and second electrode patterns 22a and 22b of the insulating substrate 20. An RF input signal may be transmitted to the lead frame 30 bonded to the first electrode pattern 22a, and an RF output signal may be transmitted to the lead frame 30 bonded to the second electrode pattern 22b.

A wire 50 may be connected to a portion of the first and second electrode patterns 22a and 22b to which the lead frame 30 is not bonded. The wire 50 may electrically connect the semiconductor chip 40 mounted on the base plate 10 and the first and second electrode patterns 22a and 22b. The wire 50 may be made of a metallic material, and for example, may be made of any one or two or more alloys selected from platinum, gold, silver, copper, and the like.

For example, the insulating substrate 20 is brazing-bonded to the base plate 10. The brazing is a method of bonding the insulating substrate 20 and the base plate 10 at an operating temperature of about 400 to 900° C. by interposing a filler layer between the insulating substrate 20 and the base plate 10, and bonds two base materials by applying heat so that the base materials are not damaged, so that it is possible to bond the two base materials while minimizing damage. At this time, the filler layer may have a structure in which one selected from Ag, Cu, and AgCu or two or more thereof are mixed. Ag, Cu, and AgCu alloys have high thermal conductivity, so that it is possible to prevent a problem from occurring in the bonded portion due to heat.

The lead frame 30 functions as an electric wire connecting the inside of the semiconductor package 1 and the outside, and may include a first surface 31 brazing-bonded to one side of each of the first electrode pattern 22a and the second electrode pattern 22b of the insulating substrate 20, and a second surface 32 formed to extend from the first surface 31 to the outside. The above-described filler layer is provided between the first and second electrode patterns 22a and 22b and the lead frame 30 so that the lead frame 30 made of a metallic material and the insulating substrate 20 made of a ceramic material may be brazing-bonded. The second surface 32 may be exposed to the outside after being completed by a molding, a casing, or the like, and connected to an external substrate (not shown).

The lead frame 30 is preferably made of a material that has the low coefficient of thermal expansion so that deformation due to heat is minimized because the lead frame 30 generates a lot of heat. A copper alloy has high electrical conductivity and thermal conductivity, but has a disadvantage in that it has the large coefficient of thermal expansion and weak strength. On the other hand, an Fe—Ni alloy (Alloy 42) or an Fe—Ni—Co alloy (KOVAR alloy) has the electrical conductivity and thermal conductivity lower than those of copper but a strength stronger than that of copper, and the Fe—Ni alloy (Alloy 42) or the Fe—Ni—Co alloy (KOVAR alloy) has the low coefficient of thermal expansion, so that it is possible to prevent the phenomenon in which a problem occurs at the bonded portion due to the thermal expansion when the Fe—Ni alloy (Alloy 42) or the Fe—Ni—Co alloy (KOVAR alloy) is applied to the lead frame 30.

For example, a cobalt (KOVAR) alloy of Fe-33Ni-4.5Co may have the coefficient of thermal expansion of 0.55 ppm/° C. in the temperature range of 20 to 100° C., an alloy (alloy 42) having a composition ratio in which iron (Fe) is 58% and nickel (Ni) is 42% may have the coefficient of thermal expansion of 5.3 ppm/° C. in the temperature range of 20 to 100° C.

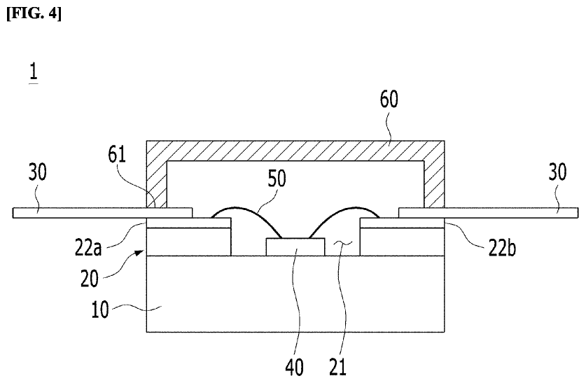

FIG. 4 is a cross-sectional view showing an example in which the casing part 60 is provided in FIG. 3.

As shown in FIG. 4, the semiconductor package 1 according to an embodiment of the present disclosure may further include the casing part 60. The casing part 60 may be bonded to the insulating substrate 20 by an adhesive or the like to seal a space above the opening 21. Here, a through groove 61 into which the lead frame 30 is inserted may be provided under the casing part 60. In other words, since the lead frame 30 is bonded to the first electrode pattern 22a and the second electrode pattern 22b of the insulating substrate 20, the casing part 60 may be provided with the through groove 61 formed in the size corresponding to the lead frame 30 to accommodate a part of the lead frame 30 and seal the space above the opening 21.

Meanwhile, although not shown, the space above the opening 21 may be sealed by a molding part (not shown). For example, the molding part may be applied to the space above the opening 21 to protect the semiconductor chip 40, a part of the lead frame 30, and the insulating substrate 20. As the molding part, silicone gel or an epoxy molded compound (EMC) may be used, but the present disclosure is not limited thereto.

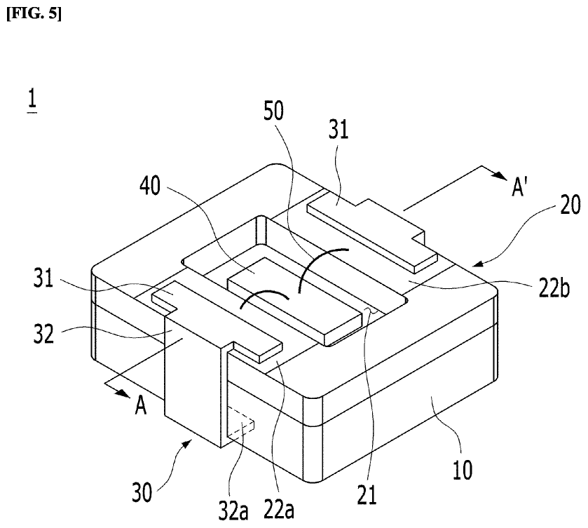

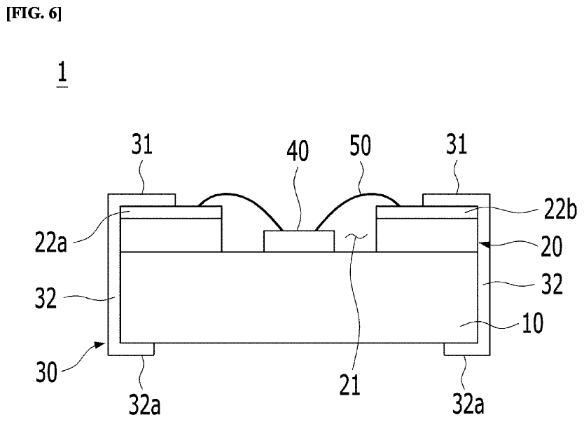

FIG. 5 is a perspective view showing an example in which a second surface of a lead frame is bent in the semiconductor package according to an embodiment of the present disclosure, and FIG. 6 is a cross-sectional view taken along line A-A′ in FIG. 5.

As shown in FIGS. 5 and 6, the lead frame 30 may have the second surface 32 bent vertically, and an end 32a of the second surface 32 may be bent along the lower surface of the base plate 10.

Here, the end 32a of the second surface 32 may be mounted on an external substrate (not shown) by soldering using a material containing lead, tin, or the like. As described above, when the second surface 32 of the lead frame 30 is vertically bent and the end 32a of the second surface 32 is bent along the lower surface of the base plate 10, the volume of the semiconductor package 1 is reduced, so that it is possible to mount more semiconductor packages 1 on the substrate.

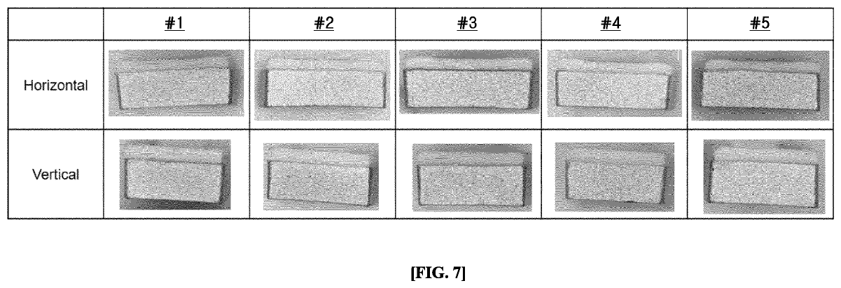

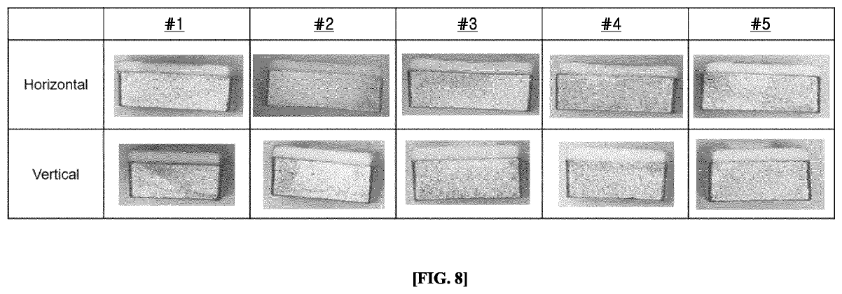

FIG. 7 is a picture showing a lateral cross section and a longitudinal cross section of a portion where an insulating substrate and a base plate are bonded in the semiconductor package according to an embodiment of the present disclosure, and FIG. 8 is a picture showing a result of performing a thermal impact test of the semiconductor package in FIG. 7.

As shown in FIGS. 7 and 8, as the result of performing the thermal impact test of 200 cycles by applying heat in the range of −55° C. to +150° C. for 15 minutes to the semiconductor package 1 according to an embodiment of the present disclosure, it may be confirmed that no problem occurs in the bonded portion between the insulating substrate 20 and the base plate 10 even after the thermal impact test. In other words, since the semiconductor package 1 according to an embodiment of the present disclosure uses the base plate 10 made of a metallic material containing Cu and Be—Cu, it may be confirmed that no problem occurs in the bonded portion between the base plate 10 and the insulating substrate 20 even when the thermal impact is applied.

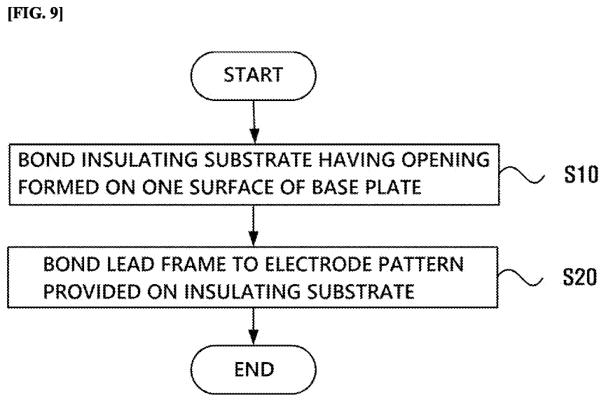

Hereinafter, a method of manufacturing the semiconductor package according to an embodiment of the present disclosure will be described with reference to FIG. 9.

FIG. 9 is a flowchart showing a manufacturing method of the semiconductor package according to an embodiment of the present disclosure.

As shown in FIG. 9, the method of manufacturing the semiconductor package according to an embodiment of the present disclosure includes bonding the insulating substrate 20 having the opening 21 to one surface of the base plate 10 (S10), and bonding the lead frame 30 to the electrode patterns 22a and 22b provided on the insulating substrate 20, in which the base plate 10 is made of a metallic material containing Cu and Be—Cu.

Copper (Cu) has the thermal conductivity of 400 W/m-K, and beryllium copper (Be—Cu) is a material in which a small amount of beryllium (Be), for example, about 0.15 to 2.75% of beryllium is alloyed with copper, and has the high thermal conductivity of 200 W/m K or more and an excellent abrasion resistance. Since copper and beryllium copper are inexpensive and have the excellent thermal conductivity, it is possible to prevent a phenomenon in which a problem occurs at the bonded portion with the insulating substrate 20 by an external temperature change, heat generated by the semiconductor chip 40, or the like when used as the base plate 10. In other words, in the semiconductor package 1 according to an embodiment of the present disclosure, it is possible to secure the reliability of the bonded portion.

Meanwhile, the method of manufacturing the semiconductor package according to an embodiment of the present disclosure may include mounting the semiconductor chip 40 in the area of the base plate 10 exposed by the opening 21. Here, the semiconductor chip may be an RF chip, and the semiconductor chip 40 mounted on the base plate 10 may be surrounded by the inner surface of the insulating substrate 20 around the opening 21.

Thereafter, the method may further include electrically connecting a portion of the electrode patterns 22a and 22b to which the lead frame 30 is not bonded and the semiconductor chip 40 using the wire 50. At this time, the wire 50 may be made of a metallic material, and for example, may be made of any one or two or more alloys selected from platinum, gold, silver, copper, and the like.

As described above, in the method of manufacturing the semiconductor package according to an embodiment of the present disclosure, since the semiconductor chip 40 is mounted on the base plate 10 having the excellent thermal conductivity containing Cu and Be—Cu, there is an advantage in that heat emitted from the semiconductor chip 40 may be quickly dissipated, and no problem occurs in the bonded portion between the insulating substrate 20 and the base plate 10 for protecting the semiconductor chip 40.

Meanwhile, the method of manufacturing the semiconductor package according to an embodiment of the present disclosure may further include vertically bending the second surface 32 formed to extend from the first surface 31 of the lead frame 30 bonded to the electrode patterns 22a and 22b to the outside, and bending the end 32a of the second surface 32 along the lower surface of the base plate 10. The bent end 32a of the second surface 32 may be mounted on an external substrate by soldering. When the second surface 32 of the lead frame 30 is bent as described above, the volume of the semiconductor package 1 is reduced, so that it is possible to mount more semiconductor packages on the substrate.

The present disclosure has been described above with reference to the exemplary drawings, but is not limited to the described embodiments, and it is apparent to those skilled in the art that the present disclosure may be variously modified and changed without departing from the spirit and scope of the present disclosure. Accordingly, these modified examples or changed examples will belong to the claims of the present disclosure, and the scope of the present disclosure should be construed based on the appended claims.

1. A semiconductor package comprising:
a base plate;
an insulating substrate bonded to the base plate, and having an opening formed therein; and
a lead frame bonded to an electrode pattern provided on the insulating substrate,
wherein the base plate is made of a metallic material including Cu and Be—Cu.

2. The semiconductor package of claim 1,
wherein the base plate has a semiconductor chip mounted on an area exposed by the opening.

3. The semiconductor package of claim 2,
wherein the semiconductor chip is an RF chip.

4. The semiconductor package of claim 2,
further including: a wire configured to electrically connect the semiconductor chip and the electrode pattern.

5. The semiconductor package of claim 4,
wherein the wire is connected to a portion of the electrode pattern in which the lead frame is not bonded.

6. The semiconductor package of claim 1,
wherein the insulating substrate has the electrode patterns provided on upper surfaces of both sides with the opening interposed therebetween.

7. The semiconductor package of claim 1,
wherein the lead frame includes:
a first surface bonded to the electrode pattern; and
a second surface formed to extend from the first surface to the outside.

8. The semiconductor package of claim 7,
wherein the lead frame has the second surface vertically bent, and an end of the second surface is bent along a lower surface of the base plate.

9. The semiconductor package of claim 1, further including: a casing part bonded to the insulating substrate to seal a space above the opening.

10. The semiconductor package of claim 9,
wherein a through groove into which the lead frame is inserted is provided under the casing part.

11. The semiconductor package of claim 1,
wherein the thermal conductivity of the base plate is 200 W/m·K or more.

12. The semiconductor package of claim 1,
wherein the insulating substrate is made of a ceramic material including 90 to 96 wt % of aluminum nitride or aluminum oxide.

13. The semiconductor package of claim 1,
wherein the lead frame is made of an Fe—Ni alloy or an Fe—Ni—Co alloy.

14. A method of manufacturing a semiconductor package, the method comprising:
bonding an insulating substrate having an opening to one surface of a base plate; and
bonding a lead frame to an electrode pattern provided on the insulating substrate,
wherein the base plate is made of a metallic material including Cu and Be—Cu.

15. The method of claim 14,
wherein the thermal conductivity of the base plate is 200 W/m·K or more.

16. The method of claim 14, further including: mounting a semiconductor chip on an area of the base plate exposed by the opening.

17. The method of claim 16, further including: electrically connecting a portion of the electrode pattern to which the lead frame is not bonded and the semiconductor chip using a wire.

18. The method of claim 14, further including: vertically bending a second surface formed to extend from a first surface of the lead frame bonded to the electrode pattern to the outside; and
bending an end of the second surface along a lower surface of the base plate.
